(19) United States
(12) Patent Application Publication
(10) Pub. No.: US 2026/0141960 A1
(43) Pub. Date: May 21, 2026

(54) MEMORY DEVICE, OPERATION METHOD, MEMORY SYSTEM AND ELECTRONIC SYSTEM

(71) Applicant: Yangtze Memory Technologies Co., Ltd., Wuhan (CN)

(72) Inventors: Wenwen DONG, Wuhan (CN); Yahai LIU, Wuhan (CN); Weijun WAN, Wuhan (CN); Wei HUANG, Wuhan (CN)

(21) Appl. No.: 19/224,515

(22) Filed: May 30, 2025

(30) Foreign Application Priority Data
Nov. 18, 2024 (CN) 202411651222.X

(51) Int. Cl. G11C 16/30

(52) U.S. Cl. CPC G11C 16/30

(57) ABSTRACT

The present application discloses a memory device, an operation method, a memory system and an electronic system. The memory device includes a memory array and a peripheral circuit, the memory device is supplied power with a first power supply, and the first power supply is coupled to the memory device. The peripheral circuit is configured to detect a power failure event of the first power supply, interrupt the target operation performed on the memory array when detecting a power failure event of the first power supply, and resume to perform the target operation in response to an operation resume condition being met.

### CROSS-REFERENCE TO RELATED APPLICATIONS

This application claims priority to Chinese Patent Application No. 202411651222.X, filed on Nov. 18, 2024, which is hereby incorporated by reference in its entirety.

### TECHNICAL FIELD

The implementations of the present application relate to the field of memory technology, and in particular to a memory device, an operating method, a memory system, and an electronic system.

### BACKGROUND

With the development of memory technology, the application of memory devices is becoming more and more extensive. The memory device can be supplied power with a first power supply, which can be configured to power other devices (such as a controller coupled to the memory device) in addition to supplying power to the memory device.

Currently, in the process of using the first power supply to supply power to the memory device, the utilization rate of the power resources provided by the first power supply needs to be improved.

### SUMMARY

Implementations of the present application provide a memory device, an operation method, a memory system and an electronic system. The technical solution is as follows:

On one hand, an implementation of the present application provides a memory device, the memory device comprising a memory array and a peripheral circuit, the memory device is supplied power with a first power supply, and the first power supply is coupled to the memory device;

The peripheral circuit is configured to detect a power failure event of the first power supply; interrupt a target operation performed on the memory array when detecting the power failure event of the first power supply; and resume to perform the target operation in response to an operation resume condition being met.

In some implementations, the peripheral circuit is further configured to establish a power supply path between the memory device and the second power supply based on the first power supply power-off instruction;

The peripheral circuit is configured to resume to perform the target operation based on the power supply to the memory device by the second power supply in response to an operation resume condition being met.

In some implementations, the peripheral circuit is further configured to disconnect a power supply path between the memory device and the first power supply based on the first power supply power-off instruction.

In some implementations, the second power supply includes a capacitor coupled to the memory device.

In some implementations, the operation resume condition being met includes an operation resume instruction being obtained.

In some implementations, the operation resume condition being met includes detecting, by the peripheral circuit, that resuming to perform the target operation is supported by a power supply situation of the memory device.

In some implementations, resuming to perform the target operation being supported by a power supply situation of the memory device, including: resuming to supply power by the first power supply in the case of the power supply path between the memory device and the first power supply being not disconnected; or a power supply path between the memory device and the second power supply being established.

In some implementations, the target operation includes at least one of a write operation or an erase operation.

In some implementations, the memory device being supplied power with a first power supply, including: the memory device being directly supplied power with the first power supply.

In some implementations, the peripheral circuit includes a power supply detection module and a control logic unit;

The power supply detection module is configured to detect a power failure event of the first power supply;

The control logic unit is configured to interrupt a target operation performed on the memory array when a power failure event of the first power supply is detected; and resume to perform the target operation in response to an operation resume condition being met.

On the other hand, an implementation of the present application provides a method of operating a memory device, wherein the memory device includes a memory array and a peripheral circuit, the memory device is supplied power with a first power supply, and the first power supply is coupled to the memory device; the method is performed by the peripheral circuit, and the method includes:

detecting a power failure event of the first power supply;

interrupting a target operation performed on the memory array when a power failure event of the first power supply is detected;

in response to the operation resume condition being met, resuming to perform the target operation.

In some implementations, the method further comprises:

establishing a power supply path between the memory device and the second power supply based on the first power supply power-off instruction;

in response to the operation resume condition being met, resuming to perform the target operation includes:

in response to an operation resume condition being met, resuming to perform the target operation based on supplying power to the memory device by the second power supply.

In some implementations, the method further comprises:

disconnecting a power supply path between the memory device and the first power supply based on the first power supply power-off instruction.

In some implementations, the second power supply includes a capacitor coupled to the memory device.

In some implementations, the operation resume condition being met includes an operation resume instruction being obtained.

In some implementations, the operation resume condition being met includes detecting, by the peripheral circuit, that resuming to perform the target operation is supported by a power supply situation of the memory device.

In some implementations, resuming to perform the target operation being supported by a power supply situation of the memory device, including: resuming the power supply by the first power supply in the case of the power supply path between the memory device and the first power supply being not disconnected; or a power supply path between the memory device and the second power supply being established.

In some implementations, the target operation includes at least one of a write operation or an erase operation.

In some implementations, the memory device being supplied power with a first power supply, including: the memory device being directly supplied power with the first power supply.

In some implementations, the peripheral circuit includes a power supply detection module and a control logic unit;

the detecting a power failure event of the first power supply includes:

detecting a power failure event of the first power supply by the power supply detection module;

interrupting the target operation performed on the memory array when a power failure event of the first power supply is detected; and the resuming to perform the target operation in response to an operation resume condition being met, comprises:

interrupting, by the control logic unit, a target operation performed on the memory array when a power failure event of the first power supply is detected; and in response to an operation resume condition being met, resuming to perform the target operation.

On the other hand, an implementation of the present application provides a memory system, the memory system comprising a memory device and a controller coupled to the memory device, the controller being configured to control the memory device;

The memory device comprises a memory array and a peripheral circuit, the memory device is supplied power with a first power supply, and the first power supply is coupled to the memory device;

The peripheral circuit is configured to detect a power failure event of the first power supply; interrupt a target operation performed on the memory array when detecting the power failure event of the first power supply; and resume to perform the target operation in response to an operation resume condition being met.

In some implementations, the controller is configured to obtain a first power supply power-off instruction and send the first power supply power-off instruction to the peripheral circuit;

The peripheral circuit is further configured to establish a power supply path between the memory device and the second power supply based on the first power supply power-off instruction sent by the controller;

The peripheral circuit is configured to resume to perform the target operation based on the power supply to the memory device by the second power supply in response to an operation resume condition being met.

In some implementations, the peripheral circuit is further configured to disconnect a power supply path between the memory device and the first power supply based on a first power supply power-off instruction sent by the controller.

In some implementations, the second power supply includes a capacitor coupled to the memory device.

In some implementations, the controller is configured to obtain an operation resume instruction and send the operation resume instruction to the peripheral circuit;

The operation resume condition being met includes an operation resume instruction sent by the controller being obtained.

In some implementations, the operation resume condition being met includes detecting, by the peripheral circuit, that resuming to perform the target operation is supported by a power supply situation of the memory device.

In some implementations, resuming to perform the target operation being supported by a power supply situation of the memory device, including: resuming the power supply by the first power supply in the case of the power supply path between the memory device and the first power supply being not disconnected; or a power supply path between the memory device and the second power supply being established.

In some implementations, the target operation includes at least one of a write operation or an erase operation.

In some implementations, the memory device being supplied power with a first power supply, including: the memory device being directly supplied power with the first power supply.

In some implementations, the peripheral circuit includes a power supply detection module and a control logic unit;

The power supply detection module is configured to detect a power failure event of the first power supply;

The control logic unit is configured to interrupt a target operation performed on the memory array when a power failure event of the first power supply is detected; and resume to perform the target operation in response to an operation resume condition being met.

On the other hand, an implementation of the present application provides an electronic system, the electronic system comprising a host and a memory system coupled to the host, the memory system comprising a memory device and a controller coupled to the memory device, the controller being configured to control the memory device;

The memory device comprises a memory array and a peripheral circuit, the memory device is supplied power with a first power supply, and the first power supply is coupled to the memory device;

The peripheral circuit is configured to detect a power failure event of the first power supply; interrupt a target operation performed on the memory array when detecting the power failure event of the first power supply; and resume to perform the target operation in response to an operation resume condition being met.

In some implementations, the host is configured to send a first power supply power-off instruction to the controller;

The controller is configured to receive a first power supply power-off instruction sent by the host, and send the first power supply power-off instruction to the peripheral circuit;

The peripheral circuit is further configured to establish a power supply path between the memory device and the second power supply based on the first power supply power-off instruction sent by the controller;

The peripheral circuit is configured to resume to perform the target operation based on the power supply to the memory device by the second power supply in response to an operation resume condition being met.

In some implementations, the peripheral circuit is further configured to disconnect a power supply path between the memory device and the first power supply based on a first power supply power-off instruction sent by the controller.

In some implementations, the peripheral circuit is further configured to store first state information in a first register within the peripheral circuit when detecting a power failure event of the first power supply, wherein the first state information is to indicate that the first power supply is in a power failure state;

The host is configured to send the first power supply power-off instruction to the controller in the case of reading the first state information from the first register.

In some implementations, the second power supply includes a capacitor coupled to the memory device.

In some implementations, the host is configured to send an operation resume instruction to the controller;

The controller is configured to receive an operation resume instruction sent by the host, and send the operation resume instruction to the peripheral circuit;

The operation resume condition being met includes an operation resume instruction sent by the controller being obtained.

In some implementations, the peripheral circuit is further configured to store second state information in a second register within the peripheral circuit when detecting that resuming to perform the target operation is supported by the power supply condition of the memory device, wherein the second state information is to indicate that resuming to perform the target operation is supported by the power supply condition of the memory device;

The host is configured to send the operation resume instruction to the controller when reading the second state information from the second register.

In some implementations, the operation resume condition being met includes detecting, by the peripheral circuit, that resuming to perform the target operation is supported by a power supply situation of the memory device.

In some implementations, resuming to perform the target operation being supported by a power supply situation of the memory device, including: resuming to supply power by the first power supply in the case of the power supply path between the memory device and the first power supply being not disconnected; or a power supply path between the memory device and the second power supply being established.

In some implementations, the target operation includes at least one of a write operation or an erase operation.

In some implementations, the memory device being supplied power with a first power supply, including: the memory device being directly supplied power with the first power supply.

In some implementations, the peripheral circuit includes a power supply detection module and a control logic unit;

The power supply detection module is configured to detect a power failure event of the first power supply;

The control logic unit is configured to interrupt a target operation performed on the memory array when a power failure event of the first power supply is detected; and resume to perform the target operation in response to an operation resume condition being met.

### BRIEF DESCRIPTION OF THE DRAWINGS

In order to more clearly illustrate the technical solutions in the implementations of the present application, the drawings required for use in the description of the implementations will be briefly introduced below. Obviously, the drawings described below are only some implementations of the present application. For the skills in the art, other drawings can be obtained based on these drawings without any creative effort.

FIG. 1 is a schematic diagram of a structure of an electronic system provided in an implementation of the present application;

FIG. 2 is a schematic diagram of a structure of a memory card provided in an implementation of the present application;

FIG. 3 is a schematic diagram of a structure of a solid-state disk provided in an implementation of the present application;

FIG. 4 is a schematic diagram of a structure of a memory device provided in an implementation of the present application;

FIG. 5 is a partial cross-sectional view of a memory array including memory strings provided in an implementation of the present application;

FIG. 6 is a schematic diagram of a structure of a peripheral circuit provided in an implementation of the present application;

FIG. 7 is a schematic diagram of processes of power supplying by a first power supply and responding to a power failure of the first power supply in an implementation;

FIG. 8 is a schematic diagram of a structure of another memory device provided in an implementation of the present application;

FIG. 9 is a schematic diagram of processes of power supplying by a first power supply and responding to a power failure of the first power supply provided by an implementation of the present application;

FIG. 10 is a flow chart of a method of operating a memory device provided in an implementation of the present application;

FIG. 11 is a schematic diagram of a structure of a memory system provided in an implementation of the present application;

FIG. 12 is a schematic diagram of a structure of another electronic system provided in an implementation of the present application.

### DETAILED DESCRIPTION

In order to make the purpose, technical solutions and advantages of the present application clearer, the implementations of the present application will be further described in detail below in conjunction with the accompanying drawings. Although implementations of the present application are shown in the accompanying drawings, it should be understood that the present application can be implemented in various forms and should not be limited by the implementations described herein. On the contrary, these implementations are provided in order to enable a more thorough understanding of the present application and to fully convey the scope of the present application to those skilled in the art. The accompanying drawings are all in a very simplified form and use non-precise proportions, which are only configured to conveniently and clearly assist in explaining the purpose of the implementations of the present application.

It should be noted that the terms “first”, “second”, etc., in this application are configured to distinguish similar objects and are not necessarily configured to describe a specific order or sequential order. It should be understood that the data used in this way can be interchangeable in appropriate circumstances, so that the implementations of the present application described here can be implemented in an order other than those illustrated or described here. The implementations described in the following implementations do not represent all implementations consistent with the present application. On the contrary, they are only examples consistent with some aspects of the present application.

It should be easily understood that the meaning of “on,” “over,” and “on . . . ” in this application should be interpreted in the broadest manner, so that “on . . . ” not only means “directly on something,” but also includes the meaning of “on something” with intervening features or layers therebetween, and “over . . . ” or “on . . . ” not only means “over something” or “on something,” but also includes the meaning of “over something” or “on something” with no intervening features or layers therebetween (i.e., directly on something).

In addition, spatially relative terms such as “below,” “beneath,” “lower,” “above,” “upper,” etc., may be used herein for ease of description to describe the relationship of one element or feature to (one or more) another element or feature as shown in the figures. The spatially relative terms are intended to encompass different orientations of the device in use or operation in addition to the orientation depicted in the figures. The device may be otherwise oriented (rotated 90 degrees or at other orientations), and the spatially relative descriptors used herein may be interpreted accordingly.

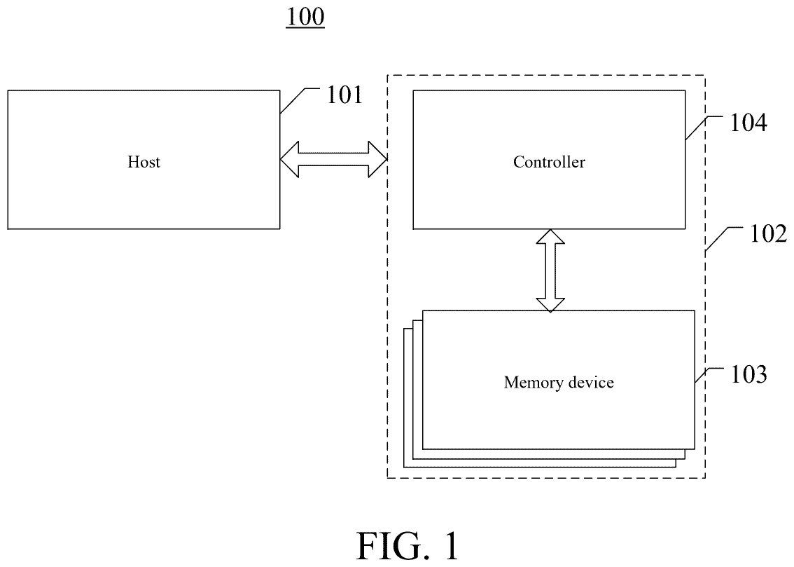

FIG. 1 shows a schematic diagram of an electronic system provided by an implementation of the present application. The electronic system 100 can be a mobile phone, a desktop computer, a laptop computer, a tablet computer, a vehicle computer, a game console, a printer, a positioning device, a wearable electronic device, a smart sensor, a virtual reality (VR) device, an augmented reality (AR) device, or any other suitable electronic device having a memory device.

As shown in FIG. 1, the electronic system 100 includes a host 101 and a memory system 102 coupled to the host 101. The host 101 may be a processor (e.g., a central processing unit (CPU)) or a system on chip (SoC) (e.g., an application processor (AP)) of an electronic device. The host 101 may be configured to send data to the memory system 102. Alternatively, the host 101 may be configured to receive data from the memory system 102.

The memory system 102 includes one or more memory devices 103 and a controller 104. The controller 104 is coupled to the memory device 103, and the controller 104 is configured to control the memory device 103. The memory device 103 can be any type of memory device. In some examples, the memory device 103 is a NAND (Not AND) flash memory device, such as a 3D NAND flash memory device; or, the memory device 103 is a DRAM (Dynamic Random Access Memory) or the like.

In some examples, the controller 104 is also coupled to the host 101. The controller 104 may manage data stored in the memory device 103 and communicate with the host 101.

In some implementations, the controller 104 is designed to operate in a low duty cycle environment, such as a Secure Digital (SD) card, a Compact Flash (CF) card, a Universal Serial Bus (USB) flash drive, or other media for use in electronic devices such as personal computers, digital cameras, mobile phones, etc.

In some implementations, the controller 104 is designed to operate in a high duty cycle environment, such as a solid-state disk (SSD) or an embedded multi-media card (eMMC). SSD or eMMC is used as data storage for mobile devices such as smartphones, tablet computers, laptops, etc., and enterprise memory arrays.

The controller 104 may be configured to control the operation of the memory device 103, such as read, erase, and program operations. The controller 104 may also be configured to manage various functions regarding data stored or to be stored in the memory device 103, including but not limited to bad block management, garbage collection, logical to physical address translation, wear leveling, etc. In some implementations, the controller 104 is also configured to process error correction codes (ECC) regarding data read from or written to the memory device 103.

The controller 104 may also perform any other suitable functions, such as formatting the memory device 103. The controller 104 may communicate with an external device (e.g., the host 101) according to a specific communication protocol. For example, the controller 104 may communicate with an external device through at least one of various interface protocols, such as a USB protocol, an MMC (Multi Media Card) protocol, a Peripheral Component Interconnect (PCI) protocol, a PCI-Express (PCI-E) protocol, an Advanced Technology Attachment (ATA) protocol, a Serial ATA protocol (SATA), a Parallel ATA protocol, a Small Computer System Interface (SCSI) protocol, an Enhanced Small Drive Interface (ESDI) protocol, an Integrated Drive Electronics (IDE) protocol, a Firewire protocol, an NVMe (Non-Volatile Memory Express) protocol, and the like.

The controller 104 and one or more memory devices 103 may be integrated into various types of memory systems 102, for example, included in the same package (e.g., Universal Flash Storage (UFS) package or eMMC package). That is, the memory system 102 may be implemented and packaged into different types of terminal electronic products.

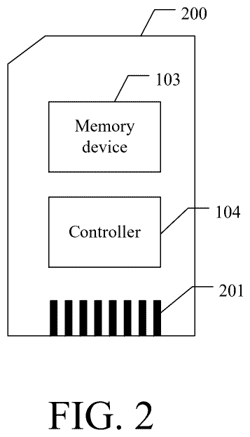

In some examples, as shown in FIG. 2, the controller 104 and the single memory device 103 may be integrated into a memory card 200. The memory card 200 may include a PC card (Personal Computer Memory Card International Association, PCMCIA, PC for short), a CF card, a Smart Media (SM) card, a memory stick, a multimedia card (MMC, RS-MMC (Reduced-Size MMC, small multimedia card), MMCmicro (micro multimedia card)), an SD card (SD, miniSD (small secure digital memory card), microSD (micro secure digital memory card), SDHC (Secure Digital High Capacity, high-capacity secure digital memory card)), UFS, etc. The memory card 200 may also include a memory card connector 201 that couples the memory card 200 with a host (e.g., the host 101 in FIG. 1).

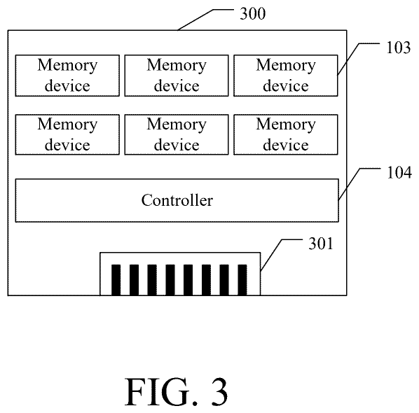

In some examples, as shown in FIG. 3, the controller 104 and the plurality of memory devices 103 may be integrated into a solid-state disk (also referred to as a solid-state drive) 300. The solid-state disk 300 may further include a solid-state disk connector 301 for coupling the solid-state disk 300 with a host (e.g., the host 101 in FIG. 1). In some implementations, at least one of the storage capacity or the operating speed of the solid-state disk 300 is greater than at least one of the storage capacity or the operating speed of the memory card 200.

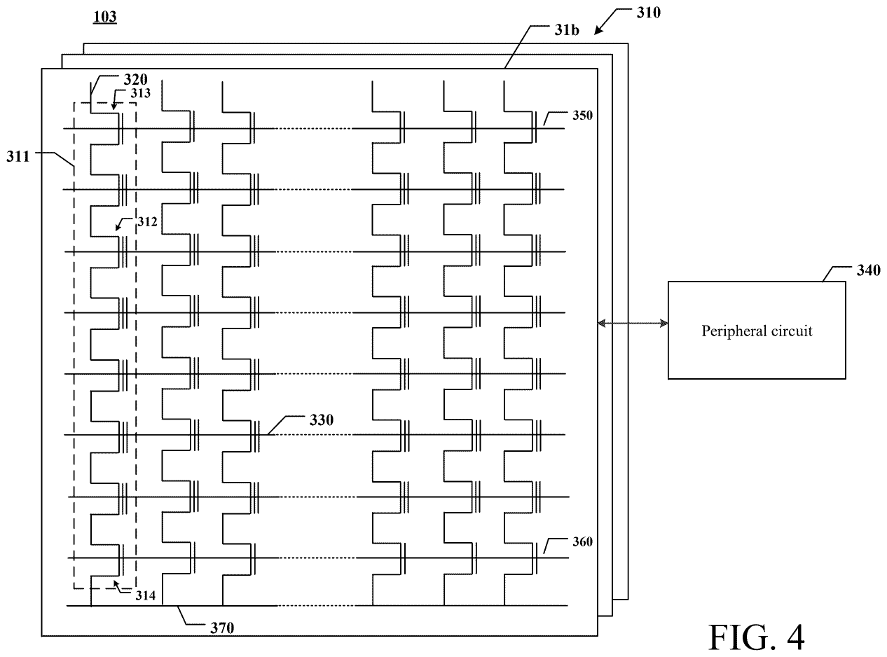

FIG. 4 shows a schematic diagram of a memory device provided by an implementation of the present application. As shown in FIG. 4, the memory device 103 includes a memory array 310 and a peripheral circuit 340. The memory array 310 is coupled to the peripheral circuit 340.

The memory array 310 includes a plurality of memory strings 311 arranged in an array, the plurality of memory strings 311 being located on a bearing side of a substrate (not shown) and extending in a direction perpendicular to a bearing surface of the substrate. In some examples, the bearing surface of the substrate refers to a surface for bearing the memory array 310 included in the substrate.

Each memory string 311 includes a plurality of memory cells 312, and the plurality of memory cells 312 in each memory string 311 are stacked in a direction perpendicular to the bearing surface of the substrate. Each memory cell 312 has the function of storing data, and the stored data is determined by the number of electrons stored in the memory cell 312, and the number of electrons stored in the memory cell 312 can determine the magnitude of the threshold voltage of the memory cell 312, so the threshold voltage of the memory cell 312 can indicate the data stored therein. The memory cell 312 is a floating gate field effect transistor or a charge trap field effect transistor.

In some examples, the memory cell 312 may be a single level cell (SLC), a multi-level cell (MLC), a triple level cell (TLC), or a quad-level cell (QLC). SLC, MLC, TLC, and QLC can store 1, 2, 3, and 4 bits of data, respectively.

Each memory string 311 also includes an upper selection tube 313 and a lower selection tube 314. The upper selection tubes 313 at the same height or similar height from the substrate bearing surface in different memory strings 311 are coupled to the same drain select line (Drain Select Line, DSL) 350. The lower selection tubes 314 at the same height or similar height from the substrate bearing surface in different memory strings 311 are coupled to the same source select line (Source Select Line, SSL) 360. Among them, the upper selection tube 313 and the lower selection tube 314 are configured to activate the selected memory string when reading, programming, or erasing the memory cell. The upper selection tube 313 is also called the top select gate (Top Select Gate, TSG), and the lower selection tube 314 is also called the bottom select gate (Bottom Select Gate, BSG). In some examples, there is also a dummy cell (Dummy Cell, DC) between the upper selection tube 313 and the memory cell 312, and between the lower selection tube 314 and the memory cell 312.

One end of the memory string 311 is coupled to a bit line (BL) 320, and the other end of the memory string 311 is coupled to a source line (SL) 370.

The memory cells 312 at the same height or similar height from the substrate bearing surface in different memory strings 311 are in the same layer, and multiple memory cells 312 in the same layer form a memory cell layer, and one memory cell layer is coupled to one word line 330, that is, the memory array 310 includes multiple memory cell layers, and the multiple memory cell layers are respectively coupled to multiple word lines 330.

In some implementations, the source terminals of each memory string 311 in the same memory block 31b are coupled to the same source line 370, which is also called a common source line (CSL). In other words, each memory string 311 in the same memory block 31b has an array common source (ACS). The source terminal of the memory string 311 refers to an end of the memory string 311 for coupling with the source line 370.

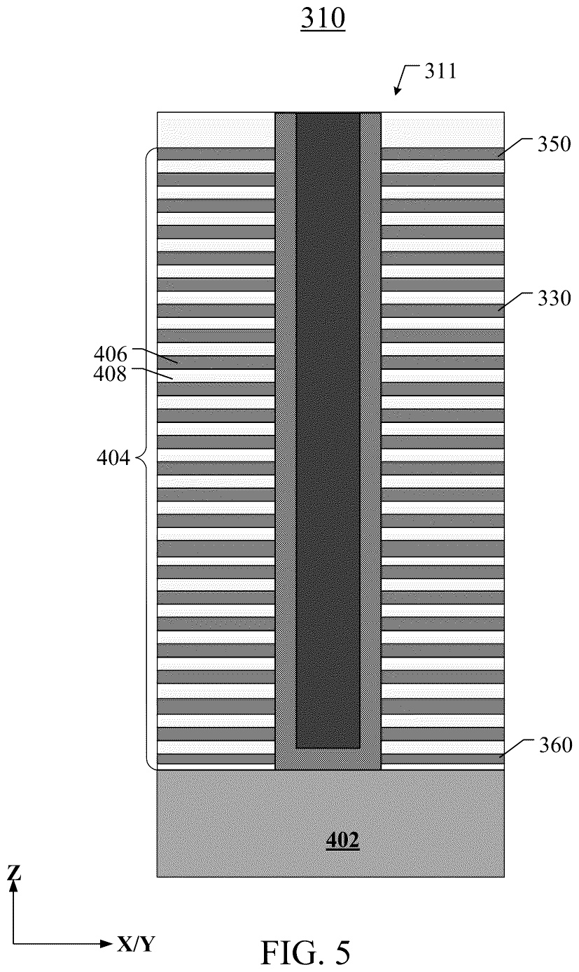

FIG. 5 shows a partial cross-sectional view of a memory array including memory strings provided in accordance with the present application. As shown in FIG. 5, the memory array 310 includes memory strings 311. The memory strings 311 may vertically extend through a memory stack 404 above a substrate 402. The substrate 402 may include silicon (e.g., single crystal silicon), silicon germanium (SiGe), gallium arsenide (GaAs), germanium (Ge), silicon on insulator (SOI), germanium on insulator (GOI), or any other suitable material.

The memory stack 404 may include alternating gate conductive layers 406 and gate-to-gate dielectric layers 408. The number of pairs of gate conductive layers 406 and gate-to-gate dielectric layers 408 in the memory stack 404 may determine the number of memory cells 312 in the memory string 311.

The gate conductive layer 406 may include a conductive material, including but not limited to tungsten (W), cobalt (Co), copper (Cu), aluminum (Al), polysilicon, doped silicon, silicide, or any combination thereof. In some implementations, each gate conductive layer 406 includes a metal layer, for example, a tungsten layer. In some implementations, each gate conductive layer 406 includes a doped polysilicon layer. Each gate conductive layer 406 may include a gate (also referred to as a control gate) surrounding the memory cell 312, and may extend laterally at the top of the memory stack 404 as a drain select line 350, extend laterally at the bottom of the memory stack 404 as a source select line 360, or extend laterally between the drain select line 350 and the source select line 360 as a word line 330.

It should be understood that, although not shown in FIG. 5, additional components of the memory array 310 may be formed including, but not limited to, gate line gaps/source contacts, local contacts, interconnect layers, and the like.

Referring back to FIG. 4, the peripheral circuit 340 may be coupled to the memory array 310 via the drain select lines 350, the source select lines 360, the bit lines 320, the source lines 370, and the word lines 330. The peripheral circuit 340 may include any suitable analog, digital, and mixed signal circuits for facilitating the operation of the memory array 310 by applying at least one of the voltage signals or current signals to the memory cells 312 via the drain select lines 350, the source select lines 360, the bit lines 320, the source lines 370, and the word lines 330, and at least one of the sensing voltage signals or current signals from the memory cells 312.

The peripheral circuit 340 may include various types of peripheral circuits formed using Metal-Oxide-Semiconductor (MOS) technology. The peripheral circuit 340 can control the memory cell 312 in the selected memory string by controlling the voltage of the word line 330 coupled to the selected memory string and the voltage of the bit line 320 coupled to the selected memory string to implement operations such as erasing, programming, reading, or verification.

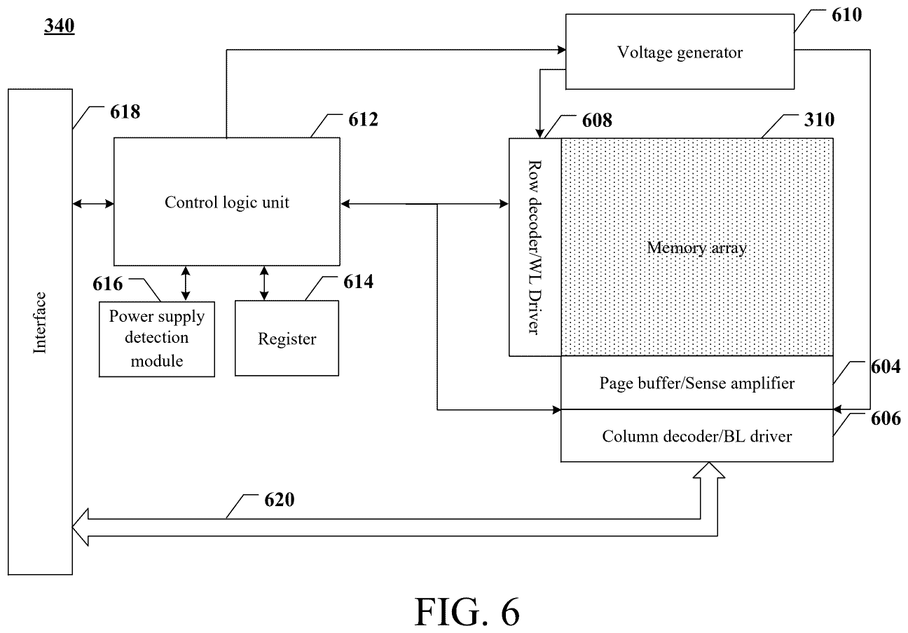

In one implementation, FIG. 6 shows an example structure of the peripheral circuit 340, which includes a page buffer/sense amplifier 604, a column decoder/bit line (BL) driver 606, a row decoder/word line (WL) driver 608, a voltage generator 610, a control logic unit 612, a register 614, a power supply detection module 616, an interface 618, and a data bus 620. It should be understood that in some examples, the peripheral circuit 340 may also include additional components not shown in FIG. 6.

The page buffer/sense amplifier 604 may be configured to read data from the memory array 310 and program (write) data to the memory array 310 according to a control signal from the control logic unit 612. In one example, the page buffer/sense amplifier 604 may store programming data (write data) to be programmed into the memory array 310. In another example, the page buffer/sense amplifier 604 may perform a program verification operation to ensure that the data has been correctly programmed into the memory cell 312 coupled to the selected word line 330. In yet another example, the page buffer/sense amplifier 604 may also sense a low-power signal from the bit line 320 representing a data bit stored in the memory cell 312, and amplify a small voltage swing to a recognizable logic level in a read operation.

The column decoder/bit line driver 606 may be configured to be controlled by the control logic unit 612, and select one or more memory strings 311 by applying a bit line voltage generated from the voltage generator 610.

The row decoder/word line driver 608 may be configured to be controlled by the control logic unit 612 and select/deselect the word line 330 of the memory block 31b of the memory array 310. The row decoder/word line driver 608 may also be configured to drive the word line 330 using the word line voltage generated from the voltage generator 610. In some implementations, the row decoder/word line driver 608 may also select/deselect and drive the drain select line 350 and the source select line 360.

The voltage generator 610 may be configured to be controlled by the control logic unit 612 and generate word line voltages (e.g., read voltages, program voltages, turn-on voltages, local voltages, verification voltages, etc.), bit line voltages, and source line voltages to be supplied to the memory array 310.

The control logic unit 612 may be coupled to each of the peripheral circuit components described above, and configured to control the operation of each of the peripheral circuit components. In an implementation, the control logic of the control logic unit 612 may be determined by firmware in the memory device 103.

The register 614 may be coupled to the control logic unit 612 and include a status register, a command register, and an address register for storing state information, a command operation code (OP code), and a command address for controlling the operation of each peripheral circuit component.

The power supply detection module 616 may be coupled to the control logic unit 612. In some examples, the power supply detection module 616 is configured to detect the type of the power supply of the memory device 103. The power supply of the memory device 103 refers to the power supply configured to supply power to the memory device 103, and the types of the power supply of the memory device 103 include but are not limited to the first power supply and the second power supply.

In some implementations, the first power supply is a general power supply. That is, in addition to being configured to supply power to the memory device 103, the first power supply can also be configured to power other devices (such as a controller coupled to the memory device 103). In other words, the first power supply is not a power supply configured to supply power to the memory device 103. The first power supply is configured to provide a higher voltage for the memory device 103, and the higher voltage is mainly used for writing operations and erasing operations. For example, the higher voltage can be expressed as Vpp (programming/erase voltage), and the value range of Vpp can be 12V (volts)±10%. In some implementations, the first power supply for providing Vpp can also be expressed as a Vpp power supply.

The second power supply refers to a power supply configured to supply power to the memory device 103. The second power supply can directly supply power to the memory device 103. That is, there is no voltage stabilization circuit between the second power supply and the memory device 103. The second power supply is configured to provide a lower voltage for the memory device 103, and the lower voltage is the basic voltage to maintain the normal operation of the memory device 103. For example, the lower voltage can be expressed as Vcc (operating voltage), and the value range of Vcc can be 2.5V±10%. In some implementations, the second power supply for providing Vcc can also be expressed as a Vcc power supply.

In some implementations, the power supply (first power supply or second power supply) can provide power to some or all components in the memory device 103 that need power supply. For example, the power supply can provide power to components such as the page buffer/sense amplifier 604, the column decoder/BL driver 606, the row decoder/WL driver 608, the voltage generator 610, the control logic unit 612, the register 614, the power supply detection module 616, and the memory array 310 in the memory device 103.

In some implementations, the power supply detection module 616 is further configured to detect whether a power failure event occurs in the first power supply when the memory device 103 is supplied power with the first power supply, and when detecting a power failure event occurs the first power supply, feed a power failure signal back to the control logic unit 612. After obtaining the power failure signal, the control logic unit 612 interrupts the current operation performed on the memory array 310, and subsequently resumes to perform the interrupted operation at an appropriate time, so as to avoid an adverse effect on the operation of the memory array by the power failure event of the first power supply.

The interface 618 may be coupled to the control logic unit 612 and act as a control buffer to buffer control commands received from a host (not shown) and relay them to the control logic unit 612, and to buffer state information received from the control logic unit 612 and relay it to the host. The interface 618 may also be coupled to the column decoder/bit line driver 606 via the data bus 620 and act as a data I/O interface and data buffer to buffer data and relay it to or from the memory array 310.

In some implementations, the number of interfaces 618 may be multiple, and the multiple interfaces 618 may include a power connection interface configured to connect to a power supply. The power supply is coupled to the memory device 103 through the power connection interface, thereby supplying power to the memory device 103.

With the development of memory technology, the application of memory devices is becoming more and more extensive. The memory device can be supplied power with a first power supply coupled to the memory device. The first power supply is a general power supply. That is, the first power supply can be configured to power other devices (such as a controller coupled to the memory device) in addition to supplying power to the memory device. In other words, the first power supply is not a power supply specially configured to supply power to the memory device. In the scenario where the memory device supports power supply by the first power supply, one power supply may be used to supply power to multiple devices, thereby enhancing the array operation of the host system by improving power efficiency, and then achieving energy saving in the array operation. In some scenarios, by using the first power supply to supply power to the memory device, a target of energy saving of about 20% can be achieved.

In some implementations, when the memory device is supplied power with the first power supply, the first power supply first passes through the voltage stabilizing circuit and then supplies power to the memory device. That is, the first power supply needs to pass through the voltage stabilizing circuit outside the memory device before supplying power to the memory device. The voltage stabilizing circuit is configured to stabilize the voltage provided by the first power supply to the memory device within a certain voltage range. When the first power supply loses power abnormally, the voltage stabilizing circuit can perform backup power so that operations related to the memory array (such as erase operations, write operations, read operations, etc.) can be successfully executed during the power failure stage. There may be some loss in the power resources provided by the first power supply after passing through the voltage stabilizing circuit, resulting in a low utilization rate of the power resources provided by the first power supply. That is, the solution in one implementation is difficult to effectively achieve the goal of energy saving.

In some implementations, the voltage stabilizing circuit includes at least one of a buck circuit and a boost circuit. In the case where the voltage stabilizing circuit includes a boost circuit and a buck circuit, the efficiency of the voltage stabilizing circuit in converting power is about 88%. That is, there may about 12% of loss in the power resources provided by the first power supply after passing through the voltage stabilizing circuit.

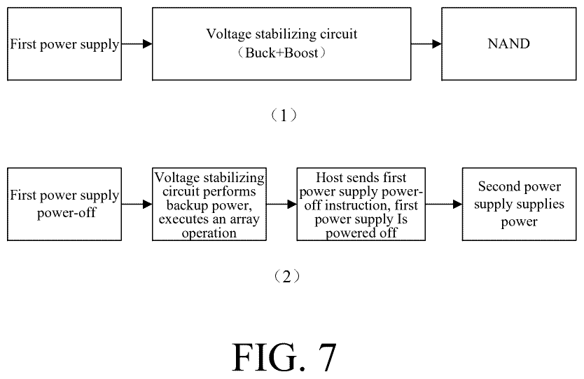

For example, the processes of supplying power by the first power supply and responding to power failure of the first power supply in one implementation may be shown in FIG. 7. The process of supplying power by the first power supply is shown in (1) of FIG. 7, where the first power supply is configured to supply power to a memory device (e.g., NAND) through a voltage stabilizing circuit (Buck circuit and Boost circuit), for example, to provide V pp for NAND, where the voltage range of V pp is 12V±10%.

The process of responding to power failure of the first power supply is shown in (2) of FIG. 7. When the first power supply fails abnormally, the first power supply performs backup power through the voltage stabilization circuit to complete the array operation which is currently executed. Afterwards, the host sends a first power supply power-off instruction to the NAND memory device. The first power supply power-off instruction is configured to power off the first power supply. After the first power supply is powered off, the second power supply supplies power.

From the above process, it can be seen that in the solution provided in an implementation, the first power supply first passes through the voltage stabilizing circuit and then supplies power to the memory device, although the voltage stabilizing circuit can perform backup power when the first power supply fails, so that operations related to the memory array can be successfully performed during the power failure stage. However, there may be some loss in the power resources provided by the first power supply after passing through the voltage stabilizing circuit, resulting in a low utilization rate of the power resources provided by the first power supply. Therefore, in the process of using the first power supply to supply power to the memory device, the utilization rate of the power resources provided by the first power supply needs to be improved.

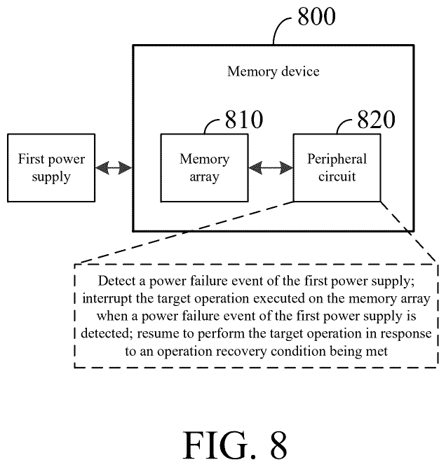

The implementation of the present application provides a memory device, and in the process of using a first power supply to supply power to such a memory device, the utilization rate of the power resources provided by the first power supply can be improved. As shown in FIG. 8, the memory device 800 provided in the implementation of the present application includes a memory array 810 and a peripheral circuit 820. The memory device 800 is supplied power with the first power supply, and the first power supply is coupled to the memory device 800. In some examples, the peripheral circuit 820 includes a plurality of interfaces, and the plurality of interfaces includes a power connection interface configured to connect to a power supply. The first power supply can be coupled to the memory device 800 through the power connection interface.

The peripheral circuit 820 is configured to detect a power failure event of the first power supply; interrupt the target operation performed on the memory array 810 when detecting the power failure event of the first power supply; and resume to perform the target operation in response to the operation resume condition being met.

In some implementations, the memory device 800 being supplied power with the first power supply, including: the memory device 800 being directly supplied power with the first power supply. That is, the first power supply can directly supply power to the memory device 800 without passing through the voltage stabilizing circuit, so as to avoid the loss of power resources provided by the voltage stabilizing circuit by the voltage stabilizing circuit.

In the implementation of the present application, in the case of the memory device 800 being supplied power with the first power supply, the peripheral circuit 820 can detect whether a power failure event occurs in the first power supply, and after detecting the power failure event of the first power supply, promptly interrupt the target operation, and resume to perform the target operation when the operation resume condition is met. Based on this, there is no need for a voltage stabilizing circuit to perform backup power, and the adverse effects on the target operation due to the power failure of the first power supply can be avoided, thereby ensuring the execution reliability of the target operation, thereby avoiding the loss of power resources provided by the first power supply by the voltage stabilizing circuit, and improving the utilization rate of the power resources provided by the first power supply.

In an implementation, the peripheral circuit 820 can detect the magnitude of the voltage provided by the first power supply. If the voltage provided by the first power supply meets the power failure condition, it is determined that a power failure event occurs in the first power supply. In some examples, the voltage provided by the first power supply meets the power failure condition, which may indicate that the voltage provided by the first power supply is less than the first voltage threshold, or that a voltage provided by the first power supply in the first time period is less than the first voltage threshold, etc. The peripheral circuit 820 can use a voltmeter, an ammeter, etc., to detect the magnitude of the voltage provided by the first power supply, which is not limited in the implementation of the present application. The first voltage threshold can be set according to experience, or it can be flexibly adjusted according to the application scenario, which is not limited in the implementation of the present application. The first time period can be set according to experience, or it can be flexibly adjusted according to the application scenario, which is not limited in the implementation of the present application.

A power failure event occurs in the first power supply, which illustrates that it is difficult to successfully perform operations related to the memory array 810 under the power supply of the first power supply. Therefore, it is necessary to interrupt the target operation in time to avoid adverse effects caused by the failure of the target operation. The target operation refers to the operation performed by the peripheral circuit 820 on the memory array 810 when a power failure event occurs in the first power supply. The implementation of the present application does not limit the type of the target operation.

In some implementations, the target operation includes at least one of a write operation, an erase operation, or a read operation. In some examples, the target operation includes a write operation, an erase operation, and a read operation. That is, when a power failure event occurs in the first power supply, no matter which basic operation the peripheral circuit 820 currently performs on the memory array 810, it is interrupted. This method can fully ensure the success rate of the basic operation performed on the memory array 810.

In other implementations, since the time required for the read operation is relatively short, even if a power failure event occurs in the first power supply, there is a high probability that the read operation will be successfully completed before the voltage provided by the first power supply drops to 0 V. Therefore, the target operation includes at least one of a write operation or an erase operation. In this case, the timeliness of the read operation can be guaranteed on the basis of ensuring the success rate of executing the write operation and the erase operation.

After interrupting the target operation performed on the memory array 810, the peripheral circuit 820 determines whether the operation resume condition is met. After determining that the operation resume condition is met, the target operation is promptly resumed to ensure the timeliness of the target operation. Meeting the operation resume condition indicates that the success rate of the current target operation is high. The specific situation of meeting the operation resume condition can be set according to experience or flexibly adjusted according to the application scenario, and the implementation of the present application does not limit this.

In some implementations, the operation resume condition being met includes detecting, by the peripheral circuit 820, that resuming to perform the target operation is supported by a power supply situation of the memory device. In this case, the peripheral circuit 820 can determine whether the operation resume condition is met by detecting the power supply condition of the memory device 800 by itself, without interacting with the host, which facilitate to improve the efficiency of determining whether the operation resume condition is met.

In an implementation, resuming to perform the target operation being supported by a power supply situation of the memory device 800, including but not limited to: in the case of the power supply path between the memory device 800 and the first power supply being not disconnected, resuming to supply power by the first power supply. When the memory device 800 is supplied power with the first power supply, a power supply path is established between the memory device 800 and the first power supply, and the peripheral circuit 820 can detect whether the first power supply resumes to supply power based on the power supply path.

The implementation of the present application does not limit the situation where the first power supply resumes to supply power. Various situations that ensure that the first power supply is not powered off and can normally supply power to the memory device 800 can all be determined as the first power supply resuming to supply power. In some examples, the first power supply resuming to supply power may indicate that the voltage provided by the first power supply is greater than the second voltage threshold, or it may indicate that a voltage provided by the first power supply in the second time period is greater than the second voltage threshold. The second voltage threshold can be set according to experience or flexibly adjusted according to the application scenario. The implementation of the present application does not limit this. The second voltage threshold can be the same as the first voltage threshold or different from the first voltage threshold. The second time period can be set according to experience or flexibly adjusted according to the application scenario. The implementation of the present application does not limit this. The second time period can be the same as the first time period or different from the first time period.

In an implementation, resuming to perform the target operation being supported by a power supply situation of the memory device 800, including but not limited to: establishing a power supply path between the memory device 800 and the second power supply. The second power supply refers to a power supply configured to supply power to the memory device 800, and the second power supply can directly supply power to the memory device 800, that is, there is no voltage stabilization circuit between the second power supply and the memory device 800. Since the second power supply is a power supply configured to supply power to the memory device 800, in the case of the power supply path between the memory device 800 and the second power supply being established, it can be considered that the memory device 800 can be stably supplied power by the second power supply, thereby determining that resuming to perform the target operation is supported by a power supply situation of the memory device.

In some implementations, the peripheral circuit 820 is further configured to establish a power supply path between the memory device 800 and the second power supply based on the first power supply power-off instruction; the peripheral circuit 820 is configured to resume to perform the target operation based on the power supply to the memory device by the second power supply 800 in response to the operation resume condition being met. In this implementation, before the operation resume condition is met, if the first power supply power-off instruction is received, the power supply is switched to the second power supply, and the target operation is performed on the basis of the power supply by the second power supply to ensure the success rate of performing the target operation.

The implementation of the present application does not limit the type of the second power supply. In some implementations, the second power supply includes a capacitor, and the capacitor is coupled to the memory device 800. In some examples, the capacitor refers to a charged capacitor, that is, the second power supply includes a capacitor coupled to the memory device 800, which has been charged according to the power supply demand of the memory device 800 before the memory device 800 is powered. This method can ensure the stability of the power supply to the memory device by the second power supply 800. In some examples, the peripheral circuit 820 includes a plurality of interfaces. The plurality of interfaces include a power connection interface configured to connect to a power supply. The capacitor can be coupled to the memory device 800 through the power connection interface.

After the first power supply power-off instruction being obtained, in addition to using the second power supply to supply power, the first power supply can also be powered off, and the peripheral circuit 820 is further configured to disconnect the power supply path between the memory device 800 and the first power supply based on the first power supply power-off instruction. Thus, by disconnecting the power supply path between the memory device 800 and the first power supply, the first power supply is powered off, thereby saving the power resources of the first power supply.

In an implementation, the peripheral circuit 820 includes a first switch circuit and a second switch circuit. The first switch circuit is configured to control the establishment and disconnection of the power supply path between the memory device 800 and the first power supply, and the second switch circuit is configured to control the establishment and disconnection of the power supply path between the memory device 800 and the second power supply. That is, the peripheral circuit 820 can implement the establishment and disconnection of the power supply path between the memory device 800 and the first power supply through the first switch circuit, and implement the establishment and disconnection of the power supply path between the memory device 800 and the second power supply through the second switch circuit. The first switch circuit can be any circuit having a switch function, and the second switch circuit can also be any circuit having a switch function. The structure of the first switch circuit can be the same as that of the second switch circuit, or it can be different from the structure of the second switch circuit.

In an implementation, the first power supply power-off instruction is an instruction initiated by the host to power off the first power supply, wherein the powering off the first power supply can be understood as disconnecting the power supply path between the memory device 800 and the first power supply, thereby stopping to supply power to the memory device 800 with the first power supply. That is, based on the first power supply power-off instruction initiated by the host, the peripheral circuit 820 disconnects the power supply path between the memory device 800 and the first power supply and establishes a power supply path between the memory device 800 and the second power supply to ensure the reliability of power switching.

In some examples, the host is coupled to a memory system where the memory device 800 is located. In addition to the memory device 800, the memory system also includes a controller coupled to the memory device 800, and the controller is configured to control the memory device 800. The process of the peripheral circuit 820 obtaining the first power supply power-off instruction includes: the host sends the first power supply power-off instruction to the controller; the controller receives the first power supply power-off instruction sent by the host and sends the first power supply power-off instruction to the peripheral circuit 820; the peripheral circuit 820 obtains the first power supply power-off instruction sent by the controller. In other words, the peripheral circuit 820 is configured to establish a power supply path between the memory device 800 and the second power supply based on the first power supply power-off instruction sent by the controller, and disconnect the power supply path between the memory device 800 and the first power supply.

In some implementations, the peripheral circuit 820 is further configured to store first state information in a first register within the peripheral circuit 820 when detecting a power failure event of the first power supply, and the first state information is to indicate that the first power supply is in a power failure state. The process of the host sending the first power supply power-off instruction to the controller includes: in the case of the host reading the first state information from the first register, the host sending the first power supply power-off instruction to the controller.

The first register may refer to any register in the peripheral circuit 820. The implementation of the present application does not limit the representation form of the first state information, as long as it may be ensured that the first state information can indicate that the first power supply is in a power failure state.

The host can periodically read information from the first register. If the information read by the host from the first register includes the first state information, it indicates that the first power supply is in a power failure state. At this time, the host issues a first power supply power-off instruction and sends the first power supply power-off instruction to the peripheral circuit 820 through the controller, so that the peripheral circuit 820 can power off the first power supply in time.

In some examples, the process of the host reading information from the first register may be: the host sends a first read instruction to the controller, and the first read instruction is configured to read information from the first register; after receiving the first read instruction sent by the host, the controller sends the first read instruction to the peripheral circuit 820; after receiving the first read instruction sent by the controller, the peripheral circuit 820 reads the information in the first register and sends the read information in the first register to the controller; after receiving the information in the first register sent by the peripheral circuit 820, the controller sends the information in the first register to the host. So far, the host has successfully read information from the first register once.

In other implementations, the operation resume condition being met includes an operation resume instruction being obtained. The operation resume instruction is an instruction issued by the host for resuming to perform the target operation. In other words, if the peripheral circuit 820 receives the operation resume instruction issued by the host, it is considered that the operation resume condition is met and the target operation is resumed to be performed. In this case, the peripheral circuit 820 determines whether the operation resume condition is met according to the instruction issued by the host, which facilitates to improve the reliability of determining whether the operation resume condition is met.

In some examples, the host is coupled to a memory system where the memory device 800 is located. In addition to the memory device 800, the memory system also includes a controller coupled to the memory device 800, and the controller is configured to control the memory device 800. The process of the peripheral circuit 820 obtaining the operation resume instruction includes: the host sends the operation resume instruction to the controller; the controller receives the operation resume instruction sent by the host and sends the operation resume instruction to the peripheral circuit 820; the peripheral circuit 820 obtains the operation resume instruction sent by the controller. In other words, the operation resume condition being met includes the peripheral circuit 820 obtaining the operation resume instruction sent by the controller.

In some implementations, the peripheral circuit 820 is further configured to store second state information in a second register within the peripheral circuit when detecting that resuming to perform the target operation is supported by a power supply situation of the memory device, and the second state information is to indicate that resuming to perform the target operation is supported by a power supply situation of the memory device 800. The process of the host sending the operation resume instruction to the controller includes: in the case of the host reading the second state information from the second register, the host sends the operation resume instruction to the controller.

The second register may refer to any register in the peripheral circuit 820, and the second register may be the same as the first register or different from the first register. The implementation of the present application does not limit the representation form of the second state information, as long as it can be ensured that the second state information can indicate that resuming to perform the target operation is supported by the power supply status of the memory device 800.

The host can periodically read information from the second register. If the information read by the host from the second register includes the second state information, it indicates that resuming to perform the target operation is supported by a power supply situation of the memory device. At this time, the host issues an operation resume instruction and sends the operation resume instruction to the peripheral circuit 820 through the controller, so that the peripheral circuit 820 can resume to perform the target operation in time.

In some examples, the process of the host reading information from the second register may be: the host sending a second read instruction to the controller, the second read instruction is configured to read information from the second register; after receiving the second read instruction sent by the host, the controller sending the second read instruction to the peripheral circuit 820; after receiving the second read instruction sent by the controller, the peripheral circuit 820 reading the information in the second register and sending the read information in the second register to the controller; after receiving the information in the second register sent by the peripheral circuit 820, the controller sends the information in the second register to the host. So far, the host has successfully read information from the second register once.

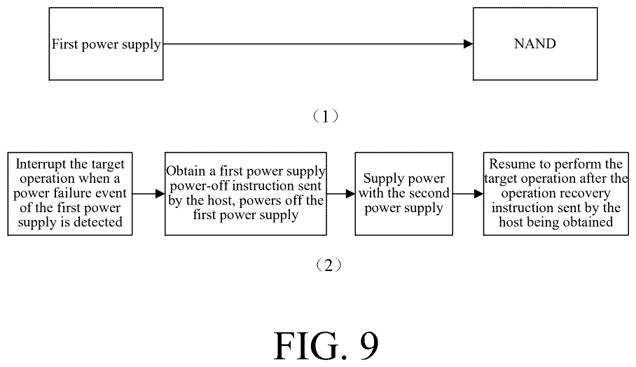

For example, the processes of supplying power by the first power supply and responding to power failure of the first power supply provided in the implementation of the present application can be shown in FIG. 9. The process of supplying power by the first power supply is shown in (1) of FIG. 9, and the first power supply directly supplies power to the NAND without passing through the voltage stabilizing circuit. The process of responding to power failure of the first power supply is shown in (2) of FIG. 9, and when detecting that a power failure event occurs in the first power supply, the peripheral circuit 820 interrupts the target operation performed on the memory array 810; after the first power supply power-off instruction issued by the host being obtained, the first power supply is powered off and the second power supply is used for supplying power. After the operation resume instruction issued by the host being obtained, the target operation is resumed to be performed.

In some examples, in the case of the target operation being a write operation, the operation resume instruction may refer to a Program Resume command for resuming the write operation, and in some implementations, the Program Resume command may be represented by code 17h. In some examples, when the target operation is an erase operation, the operation resume instruction may refer to an Erase Resume command for resuming the erase operation, and in some implementations, the Erase Resume command may be represented by code d7h.

In some implementations, the peripheral circuit 820 includes a power supply detection module and a control logic unit. The power supply detection module is configured to detect a power failure event of the first power supply; the control logic unit is configured to interrupt the target operation performed on the memory array 810 when a power failure event of the first power supply is detected; and resume to perform the target operation in response to the operation resume condition being met. In other words, the peripheral circuit 820 detects whether a power failure event occurs in the first power supply through the power supply detection module, the peripheral circuit 820 interrupts the target operation through the control logic unit, and detects whether the operation resume condition is met through the control logic unit, and resumes to perform the target operation in time when the operation resume condition is met. The peripheral circuit 820 implements different functions through different internal modules, which facilitates to improve the working standardization of the internal modules and reducing errors in the working process.

In some examples, the power supply detection module may be the power supply detection module 616 in FIG. 6, the control logic unit may be the control logic unit 612 in FIG. 6, and the peripheral circuit 820 may include other components in addition to the power supply detection module and the control logic unit, as shown in FIG. 6. For the description of the peripheral circuit 820, please refer to the description of the peripheral circuit 340 in FIG. 6 above, which will not be repeated here.

In an implementation, the power supply detection module is coupled to the control logic unit. After detecting that a power failure event occurs in the first power supply, the power supply detection module can feed back a power failure signal to the control logic unit. After obtaining the power failure signal, the control logic unit interrupts the target operation currently performed on the memory array 810. After interrupting the target operation, the control logic unit detects whether the operation resume condition is met. When the operation resume condition is met, the target operation is promptly resumed to be performed. The application implementation does not limit the representation form of the power failure signal, as long as it can identify that a power failure event occurs in the first power supply.

The memory device provided based on the implementation of the present application can provide a new type mechanism for responding to power failure of the first power supply, so that the solution may be implemented that the first power supply may supply power directly, saving the voltage stabilization circuit (such as Buck circuit and Boost circuit) and the power loss caused by the voltage stabilization circuit, and improving the power efficiency. This response mechanism can implement the interruption and resume of the target operation (such as write operation and erase operation) during the process of power failure in the first power supply on the basis of the existing interrupt response of the memory device, and the first power supply can be directly powered off without a backup power solution, thereby solving the backup power problem of the first power supply and the power efficiency conversion problem of the first power supply.

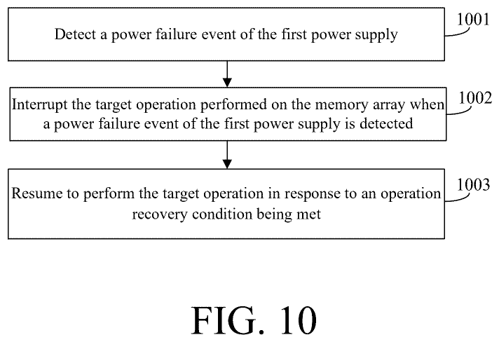

The implementation of the present application provides a method of operating a memory device. The memory device includes a memory array and a peripheral circuit. The memory device is supplied power with a first power supply, and the first power supply is coupled to the memory device. The method of operating the memory device can be executed by the peripheral circuit. The memory device can be the memory device 103 in FIG. 1-FIG. 4 or the memory device 800 in FIG. 8. Referring to FIG. 10, the method of operating the memory device includes the following operations 1001 to 1003:

operation 1001, detecting a power failure event of a first power supply.

In an implementation, the memory device being supplied power with the first power supply indicates that the memory device being directly supplied power with the first power supply.

In some implementations, the peripheral circuit includes a power supply detection module and a control logic unit. The peripheral circuit detecting a power failure event of the first power supply, including: the peripheral circuit detecting the power failure event of the first power supply through the power supply detection module.

operation 1002, when a power failure event of a first power supply is detected, interrupting a target operation performed on a memory array.

In some implementations, the target operation includes at least one of a write operation or an erase operation.

operation 1003, in response to the operation resume condition being met, resuming to perform the target operation.

In some implementations, the method further includes: establishing a power supply path between the memory device and the second power supply based on the first power supply power-off instruction. In response to the operation resume condition being met, resuming to perform the target operation includes: in response to the operation resume condition being met, based on supplying power to the memory device by the second power supply, resuming to perform the target operation.

In some implementations, the method further includes: based on the first power supply power-off instruction, disconnecting the power supply path between the memory device and the first power supply to save power resources of the first power supply.

In some examples, the second power supply includes a capacitor coupled to the memory device.

In some implementations, the operation resume condition being met includes an operation resume instruction being obtained.

In some other implementations, the operation resume condition being met includes detecting, by the peripheral circuit, that resuming to perform the target operation is supported by a power supply situation of the memory device.

In some examples, resuming to perform the target operation being supported by a power supply situation of the memory device, including: resuming to supply power by the first power supply in the case of the power supply path between the memory device and the first power supply being not disconnected; or a power supply path between the memory device and the second power supply being established.

In some implementations, the peripheral circuit includes a power supply detection module and a control logic unit, and the above operations 1002 and 1003 are implemented by the control logic unit. That is, when a power failure event of the first power supply is detected, the target operation performed on the memory array is interrupted by the control logic unit; in response to the operation resume condition being met, the target operation is resumed to be performed.

The description of implementation for the above method of operating the memory device has similar beneficial effects as the hardware implementation for the above memory device (implementation shown in FIG. 8). For technical details not disclosed in the implementation for the above method of operating the memory device, please refer to the description of the hardware implementation for the above memory device of the present application for understanding, and no further description is given here.

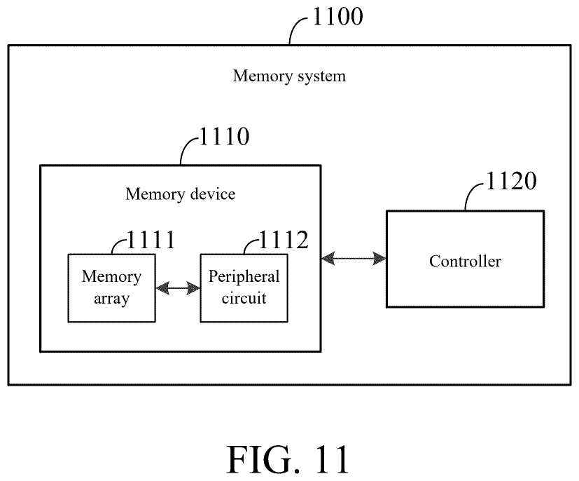

The implementation of the present application provides a memory system, as shown in FIG. 11. The memory system 1100 includes a memory device 1110 and a controller 1120 coupled to the memory device 1110. The controller 1120 is configured to control the memory device 1110; the memory device 1110 includes a memory array 1111 and a peripheral circuit 1112, the memory device 1110 is supplied power with a first power supply, and the first power supply is coupled to the memory device 1110. The controller 1120 may be the controller 104 in FIG. 1-FIG. 3 above, and the memory device 1110 may be the memory device 103 in FIG. 1-FIG. 4 above or the memory device 800 in FIG. 8.

The peripheral circuit 1112 is configured to detect a power failure event of the first power supply; interrupt the target operation performed on the memory array 1111 when detecting the power failure event of the first power supply; and resume to perform the target operation in response to an operation resume condition being met.

In some implementations, the controller 1120 is configured to obtain a first power supply power-off instruction and send the first power supply power-off instruction to the peripheral circuit 1112; the peripheral circuit 1112 is further configured to establish a power supply path between the memory device 1110 and the second power supply based on the first power supply power-off instruction sent by the controller 1120; the peripheral circuit 1112 is configured to resume to perform the target operation based on the power supply to the memory device by the second power supply 1110 in response to an operation resume condition being met.

In some implementations, the peripheral circuit 1112 is further configured to disconnect the power supply path between the memory device 1110 and the first power supply based on the first power supply power-off instruction sent by the controller 1120.

In some implementations, the second power supply includes a capacitor coupled to the memory device 1110.

In some implementations, the controller 1120 is configured to obtain an operation resume instruction and send the operation resume instruction to the peripheral circuit 1112; the operation resume condition being met includes the operation resume instruction sent by the controller 1120 being obtained.

In some implementations, the operation resume condition being met includes detecting, by the peripheral circuit 1112, that resuming to perform the target operation is supported by a power supply situation of the memory device 1110.

In some implementations, resuming to perform the target operation being supported by a power supply situation of the memory device 1110, including: resuming to supply power by the first power supply in the case of the power supply path between the memory device 1110 and the first power supply being not disconnected; or a power supply path between the memory device 1110 and the second power supply being established.

In some implementations, the target operation includes at least one of a write operation or an erase operation.

In some implementations, the memory device 1110 being supplied power with the first power supply, including: the memory device 1110 being directly supplied power with the first power supply.

In some implementations, the peripheral circuit 1112 includes a power supply detection module and a control logic unit; the power supply detection module is configured to detect a power failure event of the first power supply; the control logic unit is configured to interrupt the target operation performed on the memory array 1111 when a power failure event of the first power supply is detected; and in response to an operation resume condition being met, resume to perform the target operation.

The description of the hardware implementation of the memory system above has similar beneficial effects as the hardware implementation of the memory device (the implementation shown in FIG. 8). For technical details not disclosed in the hardware implementation of the memory system, please refer to the description of the hardware implementation of the memory device of the present application for understanding, and no further description will be given here.

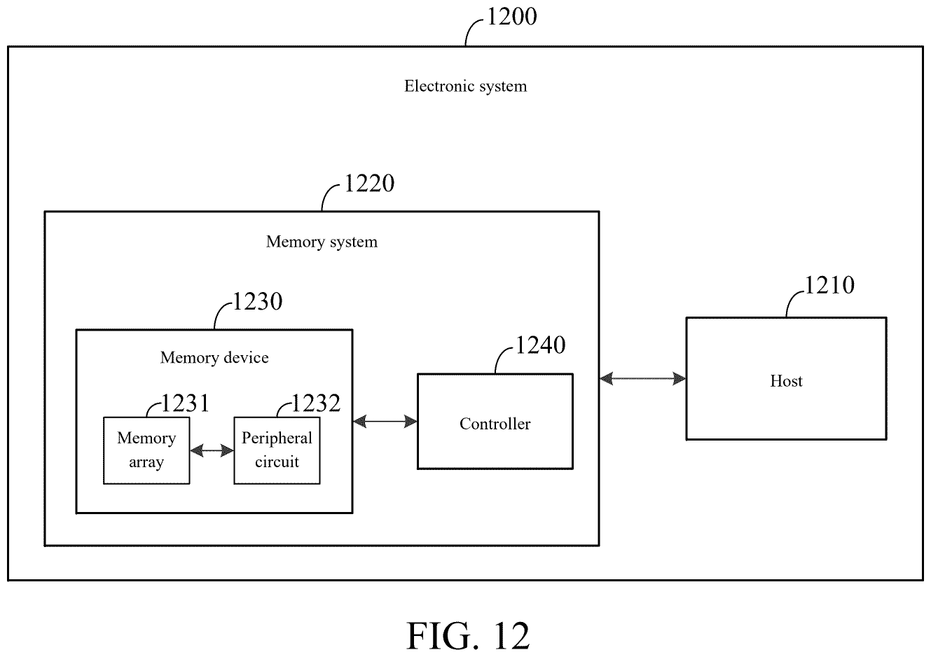

The implementation of the present application provides an electronic system, as shown in FIG. 12. The electronic system 1200 includes a host 1210 and a memory system 1220 coupled to the host 1210. The memory system 1220 includes a memory device 1230 and a controller 1240 coupled to the memory device 1230. The controller 1240 is configured to control the memory device 1230. The memory device 1230 includes a memory array 1231 and a peripheral circuit 1232. The memory device 1230 is supplied power with a first power supply, and the first power supply is coupled to the memory device 1230. In some examples, the electronic system 1200 may be the electronic system 100 in FIG. 1, the host 1210 may be the host 101 in FIG. 1, and the memory system 1220 may be the memory system 102 in FIG. 1 or the memory system 1100 in FIG. 11. The memory device 1230 may be the memory device 103 in FIG. 1-FIG. 4 or the memory device 800 in FIG. 8, and the controller 1240 may be the controller 104 in FIG. 1-FIG. 3.

The peripheral circuit 1232 is configured to detect a power failure event of the first power supply; interrupt the target operation performed on the memory array 1231 when detecting the power failure event of the first power supply; and resume to perform the target operation in response to the operation resume condition being met.

In some implementations, the host 1210 is configured to send a first power supply power-off instruction to the controller 1240; the controller 1240 is configured to receive the first power supply power-off instruction sent by the host 1210, and send the first power supply power-off instruction to the peripheral circuit 1232; the peripheral circuit 1232 is further configured to establish a power supply path between the memory device 1230 and the second power supply based on the first power supply power-off instruction sent by the controller 1240; the peripheral circuit 1232 is configured to resume to perform the target operation based on the power supply to the memory device by the second power supply 1230 in response to an operation resume condition being met.

In some implementations, the peripheral circuit 1232 is further configured to disconnect the power supply path between the memory device 1230 and the first power supply based on the first power supply power-off instruction sent by the controller 1240.

In some implementations, the peripheral circuit 1232 is further configured to store first state information in a first register within the peripheral circuit 1232 when detecting a power failure event of the first power supply, and the first state information is to indicate that the first power supply is in a power failure state; the host 1210 is configured to send a first power supply power-off instruction to the controller 1240 when reading the first state information from the first register.

In some implementations, the second power supply includes a capacitor coupled to the memory device 1230.

In some implementations, the host 1210 is configured to send an operation resume instruction to the controller 1240; the controller 1240 is configured to receive the operation resume instruction sent by the host 1210 and send the operation resume instruction to the peripheral circuit 1232; the operation resume condition being met includes the operation resume instruction sent by the controller 1240 being obtained

In some implementations, the peripheral circuit 1232 is further configured to store second state information in a second register within the peripheral circuit 1232 when detecting the resuming to perform the target operation is supported by a power supply situation of the memory device 1230, and the second state information is to indicate that resuming to perform the target operation is supported by a power supply situation of the memory device 1230; the host 1210 is configured to send an operation resume instruction to the controller 1240 in the case of reading the second state information from the second register.

In some implementations, the operation resume condition being met includes detecting, by the peripheral circuit 1232, that resuming to perform the target operation is supported by a power supply situation of the memory device 1230.

In some implementations, resuming to perform the target operation being supported by a power supply situation of the memory device 1230, including: resuming to supply power by the first power supply in the case of the power supply path between the memory device 1230 and the first power supply being not disconnected; or a power supply path between the memory device 1230 and the second power supply being established.

In some implementations, the target operation includes at least one of a write operation or an erase operation.

In some implementations, the memory device 1230 being supplied power with the first power supply, including: the memory device 1230 being directly supplied power with the first power supply.

In some implementations, the peripheral circuit 1232 includes a power supply detection module and a control logic unit; the power supply detection module is configured to detect a power failure event of the first power supply; the control logic unit is configured to interrupt the target operation performed on the memory array 1231 when a power failure event of the first power supply is detected; and in response to an operation resume condition being met, resume to perform the target operation.

The description of the hardware implementation of the electronic system above has similar beneficial effects as the hardware implementation of the memory device above (the implementation shown in FIG. 8). For technical details not disclosed in the hardware implementation of the electronic system, please refer to the description of the hardware implementation of the memory device of the present application for understanding, and no further description will be given here.

It should be understood that the “plurality” mentioned in this article refers to two or more. “And/or” describes the association relationship of the associated objects, indicating that there can be three relationships. For example, A and/or B can mean: A exists alone, A and B exist at the same time, and B exists alone. The character “/” generally indicates that the associated objects are in an “or” relationship.

The above description is only an implementation of the present application and is not intended to limit the present application. Any modifications, equivalent substitutions, improvements, etc., made within the principles of the present application shall be included in the protection scope of the present application.

What is claimed is:

1. A memory device, wherein the memory device is supplied power with a first power supply, and the first power supply is coupled to the memory device, the memory device comprising:
a memory array; and
a peripheral circuit configured to:
detect a power failure event of the first power supply;
interrupt a target operation performed on the memory array when detecting the power failure event of the first power supply; and
resume to perform the target operation in response to an operation resume condition being met.

2. The memory device of claim 1, wherein the peripheral circuit is further configured to:
establish a power supply path between the memory device and a second power supply based on a first power supply power-off instruction; and
resume to perform the target operation based on power supply to the memory device by the second power supply in response to an operation resume condition being met.

3. The memory device of claim 2, wherein the peripheral circuit is further configured to disconnect a power supply path between the memory device and the first power supply based on the first power supply power-off instruction.

4. The memory device of claim 2, wherein the second power supply comprises a capacitor coupled to the memory device.

5. The memory device of claim 1, wherein the operation resume condition being met comprises an operation resume instruction being obtained.

6. The memory device of claim 2, wherein the operation resume condition being met comprises detecting, by the peripheral circuit, that resuming to perform the target operation is supported by a power supply situation of the memory device.

7. The memory device of claim 6, wherein resuming to perform the target operation being supported by a power supply situation of the memory device comprises:
resuming to supply power by the first power supply when the power supply path between the memory device and the first power supply are connected; or
a power supply path between the memory device and the second power supply being established.

8. The memory device of claim 1, wherein the target operation comprises at least one of a write operation or an erase operation.

9. The memory device of claim 1, wherein the memory device being supplied power with a first power supply comprises: the memory device being directly supplied power with the first power supply.

10. The memory device of claim 1, wherein the peripheral circuit comprises:
a power supply detection module configured to detect a power failure event of the first power supply; and
a control logic unit configured to:
interrupt a target operation performed on the memory array when a power failure event of the first power supply is detected; and
resume to perform the target operation in response to an operation resume condition being met.

11. A memory system, comprising:
a memory device, wherein the memory device is supplied power with a first power supply, and the first power supply is coupled to the memory device, the memory device comprising:
a memory array; and
a peripheral circuit configured to:
detect a power failure event of the first power supply;
interrupt a target operation performed on the memory array when detecting the power failure event of the first power supply; and
resume to perform the target operation in response to an operation resume condition being met; and
a controller coupled to the memory device, and configured to control the memory device.

12. The memory system of claim 11, wherein the controller is configured to obtain a first power supply power-off instruction, send the first power supply power-off instruction to the peripheral circuit;
the peripheral circuit is configured to:
establish a power supply path between the memory device and a second power supply based on the first power supply power-off instruction sent by the controller; and
resume to perform the target operation based on power supply to the memory device by the second power supply in response to an operation resume condition being met.

13. The memory system of claim 12, wherein the peripheral circuit is further configured to disconnect a power supply path between the memory device and the first power supply based on a first power supply power-off instruction sent by the controller.

14. The memory system of claim 11, wherein the controller is configured to obtain an operation resume instruction, send the operation resume instruction to the peripheral circuit; and
the operation resume condition being met comprises an operation resume instruction sent by the controller being obtained.

15. An electronic system, comprising:
a host; and
a memory system coupled to the host, the memory system comprising:
a memory device, wherein the memory device is supplied power with a first power supply, and the first power supply is coupled to the memory device, and the memory device comprising:
a memory array; and
a peripheral circuit configured to:
detect a power failure event of the first power supply;
interrupt a target operation performed on the memory array when detecting the power failure event of the first power supply; and
resume to perform the target operation in response to an operation resume condition being met; and
a controller coupled to the memory device, and configured to: control the memory device.

16. The electronic system of claim 15, wherein the host is configured to send a first power supply power-off instruction to the controller;
the controller is configured to receive the first power supply power-off instruction sent by the host, send the first power supply power-off instruction to the peripheral circuit; and
the peripheral circuit is configured to:
establish a power supply path between the memory device and a second power supply based on the first power supply power-off instruction sent by the controller; and
resume to perform the target operation based on a power supply to the memory device by the second power supply in response to an operation resume condition being met.

17. The electronic system of claim 16, wherein the peripheral circuit is further configured to disconnect a power supply path between the memory device and the first power supply based on the first power supply power-off instruction sent by the controller.

18. The electronic system of claim 16, wherein the peripheral circuit is further configured to store a first state information in a first register within the peripheral circuit when detecting a power failure event of the first power supply, wherein the first state information is to indicate that the first power supply is in a power failure state; and
the host is configured to send the first power supply power-off instruction to the controller when reading the first state information from the first register.

19. The electronic system of claim 15, wherein the host is configured to send an operation resume instruction to the controller;
the controller is configured to receive an operation resume instruction sent by the host, send the operation resume instruction to the peripheral circuit; and
the operation resume condition being met comprises an operation resume instruction sent by the controller being obtained.

20. The electronic system of claim 19, wherein the peripheral circuit is further configured to store a second state information in a second register within the peripheral circuit when detecting that resuming to perform the target operation is supported by a power supply situation of the memory device, wherein the second state information is to indicate that resuming to perform the target operation is supported by a power supply situation of the memory device; and
the host is configured to send the operation resume instruction to the controller when reading the second state information from the second register.
